(19) United States
(12) Patent Application Publication
(10) Pub. No.: US 2025/0284208 A1
(43) Pub. Date: Sep. 11, 2025

(54) Methods And Systems For Real Time Robust Control Of Machine Learning Based Measurement Recipe Optimization

(71) Applicant: KLA Corporation, Milpitas, CA (US)

(72) Inventor: Stilian Ivanov Pandev, Santa Clara, CA (US)

(21) Appl. No.: 19/035,501

(22) Filed: Jan. 23, 2025

Related U.S. Application Data
(60) Provisional application No. 63/555,892, filed on Feb. 21, 2024.

(51) Int. Cl. G03F 7/00

(52) U.S. Cl. CPC G03F 7/706833; G03F 7/706839

(57) ABSTRACT

Methods and systems for training a machine learning based measurement model conditioned by at least one regularization control parameter are described herein. A ML based measurement model conditioned by at least one regularization control parameter is trained for different control parameter values. A regularization control value provided as input to the trained ML based measurement model defines the regularization condition at inference. In a further aspect, an optimal value of a regularization control parameter is selected based on measurement performance on a set of measurement data. As measurement conditions change, the optimal value is reevaluated based on measurement performance on an updated set of measurement data that reflects the changing measurement conditions. In another further aspect, changes in measurement conditions and reevaluation of a regularization control value are performed automatically as measurement data is collected by a measurement system without interruption of the measurement process.

### CROSS REFERENCE TO RELATED APPLICATION

The present application for patent claims priority under 35 U.S.C. § 119 from U.S. provisional patent application Ser. No. 63/555,892, entitled “Method for Real Time Robustness Control of Metrology Recipe,” filed Feb. 21, 2024, the subject matter of which is incorporated herein by reference in its entirety.

### TECHNICAL FIELD

The described embodiments relate to metrology systems and methods, and more particularly to methods and systems for improved measurement of semiconductor structures.

### BACKGROUND INFORMATION

Semiconductor devices such as logic and memory devices are typically fabricated by a sequence of processing steps applied to a specimen. The various features and multiple structural levels of the semiconductor devices are formed by these processing steps. For example, lithography among others is one semiconductor fabrication process that involves generating a pattern on a semiconductor wafer. Additional examples of semiconductor fabrication processes include, but are not limited to, chemical-mechanical polishing, etch, deposition, and ion implantation. Multiple semiconductor devices may be fabricated on a single semiconductor wafer and then separated into individual semiconductor devices.

Metrology processes are used at various steps during a semiconductor manufacturing process to detect defects on wafers to promote higher yield. Optical and X-ray based metrology techniques offer the potential for high throughput without the risk of sample destruction. A number of metrology based techniques including scatterometry, reflectometry, and ellipsometry implementations and associated analysis algorithms are commonly used to characterize critical dimensions, film thicknesses, composition, overlay and other parameters of nanoscale structures.

Many metrology techniques are indirect methods of measuring physical properties of a specimen under measurement. In most cases, the raw measurement signals cannot be used to directly determine the physical properties of the specimen. Instead, a measurement model is employed to estimate the values of one or more parameters of interest based on the raw measurement signals. In some examples, a trained machine learning based measurement model is employed to directly estimate values of parameters of interest based on raw measurement data. In these examples, a machine learning based measurement model takes raw measurement signals as model input and generates values of the parameters of interest as model output.

Machine learning based measurement models must be trained to generate useful estimates of parameters of interest for a particular measurement application. Generally, model training is based on raw measurement signals collected from specimen having known values of the parameters of interest (i.e., Design of Experiments (DOE) data). A machine learning based measurement model is parameterized by a number of weight parameters. Traditionally, the machine learning based measurement model is trained by a regression process (e.g., ordinary least squares regression). The values of the weight parameters are iteratively adjusted to minimize the differences between the known, reference values of the parameters of interest and values of the parameters of interest estimated by the machine learning based measurement model based on the measured raw measurement signals.

In the absence of regularization, the training of a machine learning based measurement model (a.k.a., measurement recipe generation) is achieved by minimizing total output error; typically expressed as a least squares minimization. Total output error is an expression of total measurement uncertainty; an aggregation of all of the errors arising from the measurement, including precision errors, tool-to-tool matching errors, parameter tracking errors, within wafer variations, etc. Unfortunately, model training based on total measurement uncertainty without regularization of the components of the total measurement uncertainty leads to suboptimal measurement performance. In many examples, large modeling errors arise, particularly when training is performed based on simulated data due to discrepancies between simulated and real data.

To reduce modeling errors, the training of a machine learning based measurement model is performed with regularization. A regularization control value is selected as a hyperparameter controlling regularization during training. In the current model development approach, different machine learning based measurement models are separately trained, each associated with a different regularization control value. The trained ML based measurement model exhibiting the best measurement performance on the training data set, an evaluation data set, or both, is selected as the trained ML based measurement model employed to perform measurements of unknown wafer targets. Unfortunately, this approach requires training of multiple ML based measurement models, which is costly in terms of computational effort and time.

In addition, this approach is not robust to changing process conditions. As process conditions drift over time, measurement errors become unacceptably large as the distribution of raw measurement data drifts away from the measurement data employed to validate the trained ML based measurement model.

To overcome this problem, the ML based measurement model is trained multiple times on the measurement data sets corresponding to the changed process conditions. Each different ML based measurement model is trained at a different regularization control value. The trained ML based measurement model exhibiting the best measurement performance on the measurement data sets corresponding to the changed process conditions is selected as the trained ML based measurement model employed to perform measurements of unknown wafer targets. Again, this approach requires training of multiple ML based measurement models, which is costly in terms of computational effort and time. Moreover, the selected model is only valid over a small window of process conditions. When process conditions drift beyond this window, the costly training process must be repeated. Overall, this approach is costly in terms of time and computational effort, and suffers from a lack of measurement robustness.

Future metrology applications present challenges for metrology due to increasingly small resolution requirements, multi-parameter correlation, increasingly complex geometric structures, and increasing use of opaque materials. Thus, methods and systems for improved measurement recipe generation are desired.

### SUMMARY

Methods and systems for training a machine learning based measurement model conditioned by at least one regularization control parameter are described herein. An ensemble of values of at least one regularization control parameter is employed to control the regularization of the optimization process employed during measurement model training. As a result, a regularization conditioned ML based measurement model is trained for different regularization conditions. A regularization control value provided as a conditional input to the trained ML based measurement model defines the regularization condition at inference.

In one aspect, an ML based measurement model is trained over an ensemble of values of each regularization control parameter. Each regularization control value in the ensemble corresponds to a different level of regularization. As a result, the trained ML based measurement model is optimized for any value of the regularization control parameter within the range of values of the regularization control parameter employed during training. This enables the trained ML based measurement model to capture a broader range of variations in the measurement data, and thus, significantly extends the range of process conditions for which the trained ML based measurement model is capable of providing accurate measurements. A ML based measurement model conditioned by at least one regularization control parameter improves model robustness to measurement data outside the distribution of Design Of Experiments (DOE) measurement data employed to train the model.

In a further aspect, an optimal value of a regularization control parameter is provided as input to the trained ML based measurement model at inference. The optimal value is selected based on measurement performance on a set of measurement data. As measurement conditions change, the optimal value is reevaluated based on the measurement performance on an updated set of measurement data that reflects the changing measurement conditions. In this manner, the measurement performance of the trained ML based measurement model adapts to changing measurement conditions by updating the regularization control value, rather than retraining the entire measurement model.

In another further aspect, changes in measurement conditions and reevaluation of a regularization control value are performed automatically as measurement data is collected by a measurement system. In this manner, the trained ML based measurement model adapts to changing measurement conditions without disrupting the measurement process.

The foregoing is a summary and thus contains, by necessity, simplifications, generalizations and omissions of detail; consequently, those skilled in the art will appreciate that the summary is illustrative only and is not limiting in any way. Other aspects, inventive features, and advantages of the devices and/or processes described herein will become apparent in the non-limiting detailed description set forth herein.

### BRIEF DESCRIPTION OF THE DRAWINGS

FIG. 1 depicts an illustration of an embodiment of a wafer metrology system for measuring characteristics of a wafer in accordance with the exemplary methods presented herein.

FIG. 2 is a diagram illustrative of an exemplary regularization conditioned measurement model training engine in one embodiment.

FIG. 3 is a diagram illustrative of an exemplary regularization control parameter optimization engine in one embodiment.

FIG. 4 is a plot illustrative of exemplary metrics characterizing measurement tracking performance.

FIG. 5 is a diagram illustrative of an exemplary trained regularization conditioned measurement engine in one embodiment.

FIG. 6 is a diagram illustrative of a regularization block of a trained regularization conditioned measurement model in one embodiment.

FIG. 7 is a plot illustrative of the root mean square error (RMSE) associated with the estimation of a metal gate critical dimension (MGCD) by a trained measurement model with regularization conditioned by a regularization control value ranging from zero to one.

FIG. 8 is another plot of the root mean square error (RMSE) associated with the estimation of an inner spacer critical dimension (ISCD) by a trained measurement model with regularization conditioned by a regularization control value ranging from zero to one for two different measurement data sets.

FIG. 9 is a diagram illustrative of an exemplary regularization control parameter optimization engine in another embodiment.

FIG. 10 illustrates a flowchart of a method for training a regularization conditioned measurement model for estimating values of parameters of interest in one example.

### DETAILED DESCRIPTION

Reference will now be made in detail to background examples and some embodiments of the invention, examples of which are illustrated in the accompanying drawings.

Methods and systems for training a machine learning based measurement model conditioned by at least one regularization control parameter are described herein. A ML based measurement model conditioned by at least one regularization control parameter is trained for different regularization conditions. An ensemble of values of at least one regularization control parameter is employed to control the regularization of the optimization process employed during measurement model training. A regularization control value provided as input to the trained ML based measurement model defines the regularization condition at inference. The value of each regularization control parameter is treated as a conditional input to the ML based measurement model.

In one aspect, an ML based measurement model is trained over an ensemble of values of each regularization control parameter. Each regularization control value in the ensemble corresponds to a different level of regularization. In this manner, the optimization process is conditioned on the value of the regularization control parameter. As a result, the trained ML based measurement model is optimized for any value of the regularization control parameter within the range of values of the regularization control parameter employed during training. This enables the trained ML based measurement model to capture a broader range of variations in the measurement data, and thus, significantly extends the range of process conditions for which the trained ML based measurement model is capable of providing accurate measurements. A ML based measurement model conditioned by at least one regularization control parameter improves model robustness to measurement data outside the distribution of Design Of Experiments (DOE) measurement data employed to train the model.

In a further aspect, an optimal value of a regularization control parameter is provided as input to the trained ML based measurement model at inference. The optimal value is selected based on measurement performance on a set of measurement data. As measurement conditions change, the optimal value is reevaluated based on the measurement performance on an updated set of measurement data that reflects the changing measurement conditions. In this manner, the measurement performance of the trained ML based measurement model adapts to changing measurement conditions by updating the regularization control value, rather than retraining the entire measurement model.

In another further aspect, changes in measurement conditions and reevaluation of a regularization control value are performed automatically as measurement data is collected by a measurement system. In this manner, the trained ML based measurement model adapts to changing measurement conditions without disrupting the measurement process.

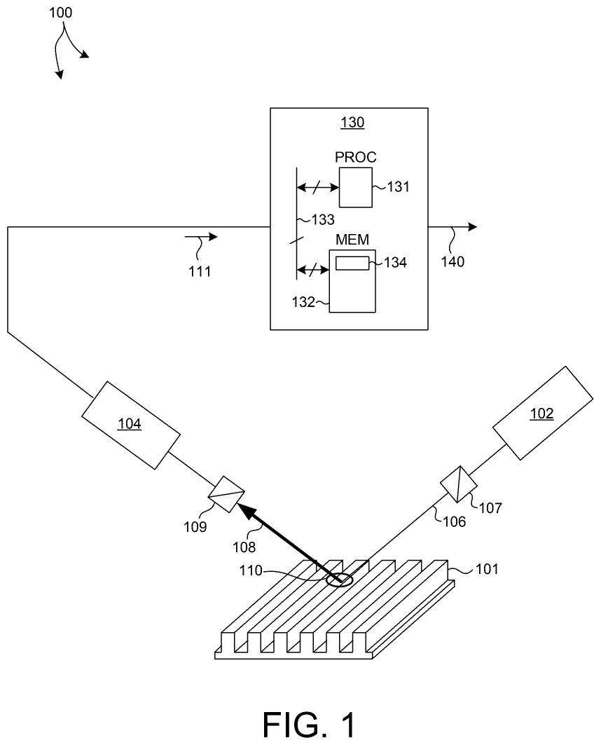

FIG. 1 illustrates a system 100 for measuring characteristics of a specimen in accordance with the exemplary methods presented herein. As shown in FIG. 1, the system 100 may be used to perform spectroscopic ellipsometry measurements of structure 101 depicted in FIG. 1. In this aspect, the system 100 may include a spectroscopic ellipsometer equipped with an illuminator 102 and a spectrometer 104. The illuminator 102 of the system 100 is configured to generate and direct illumination of a selected wavelength range (e.g., 100-2500 nm) to the structure disposed on the surface of the specimen over a measurement spot 110. In turn, the spectrometer 104 is configured to receive illumination reflected from structure 101. It is further noted that the light emerging from the illuminator 102 is polarized using a polarization state generator 107 to produce a polarized illumination beam 106. The radiation reflected by structure 101 is passed through a polarization state analyzer 109 and to the spectrometer 104. The radiation received by the spectrometer 104 in the collection beam 108 is analyzed with regard to polarization state, allowing for spectral analysis by the spectrometer of radiation passed by the analyzer. These spectra 111 are passed to the computing system 130 for analysis of the structure as described herein.

As depicted in FIG. 1, system 100 includes a single measurement technology (i.e., SE). However, in general, system 100 may include any number of different measurement technologies. By way of non-limiting example, system 100 may be configured as a spectroscopic ellipsometer (including Mueller matrix ellipsometry), a spectroscopic reflectometer, a spectroscopic scatterometer, an overlay scatterometer, an angular resolved beam profile reflectometer, a polarization resolved beam profile reflectometer, a beam profile reflectometer, a beam profile ellipsometer, any single or multiple wavelength ellipsometer, or any combination thereof. Furthermore, in general, measurement data collected by different measurement technologies and analyzed in accordance with the methods described herein may be collected from multiple tools, a single tool integrating multiple technologies, or a combination thereof, including, by way of non-limiting example, soft X-ray reflectometry, small angle x-ray scatterometry, an imaging based metrology system, a hyperspectral imaging based metrology system, a scatterometry overlay metrology system, etc.

In a further embodiment, system 100 may include one or more computing systems 130 employed to perform measurements of structures based on measurement models developed in accordance with the methods described herein. The one or more computing systems 130 may be communicatively coupled to the spectrometer 104. In one aspect, the one or more computing systems 130 are configured to receive measurement data 111 associated with measurements of a structure under measurement (e.g., structure 101).

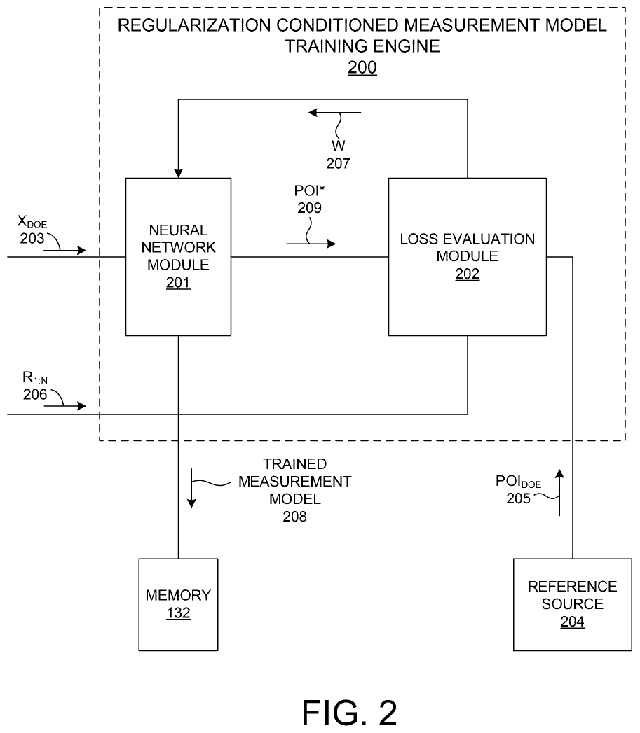

In one aspect, computing system 130 is configured as a measurement model training engine 150 to train a measurement model based on measurements of regularization structures as described herein. FIG. 2 is a diagram illustrative of an exemplary regularization conditioned measurement model training engine 200 in one embodiment. As depicted in FIG. 2, regularization conditioned measurement model training engine 200 receives measurement data, X_{DOE} 203, associated with simulated measurements, actual measurements, or both, of multiple instances of one or more Design of Experiments (DOE) metrology targets disposed on one or more wafers. In an example of a spectroscopic ellipsometer measurement, the DOE measurement data includes measured spectra, simulated spectra, or both. In one example, the DOE measurement data 203 includes measured spectra 111 collected by metrology system 100 from multiple instances of one or more DOE metrology targets.

In addition, measurement model training engine 200 receives reference values of one or more parameters of interest, POI_{DOE} 205, associated with the DOE metrology targets from a reference source 204. Examples of parameters of interest include geometric parameters characterizing a measured structure, dispersion parameters characterizing a measured structure, process parameters characterizing a process employed to fabricate a measured structure, electrical properties of the measured structure, etc. Exemplary geometric parameters include critical dimensions (CD), overlay, etc. Exemplary process parameters include lithography focus, lithography dosage, etch time, etc.

In some embodiments, the reference values 205 are simulated. In these embodiments, the reference source 204 is a simulation engine that generates the corresponding simulated DOE measurement data 203 for known reference values 205. In some embodiments, the reference values 205 are values measured by a trusted measurement system (e.g., a scanning electron microscope, etc.). In these embodiments, the reference source is the trusted measurement system.

In some embodiments, values of parameters of interest employed to train a measurement model are derived from measurements of DOE wafers by a reference metrology system. The reference metrology system is a trusted measurement system that generates sufficiently accurate measurement results. In some examples, reference metrology systems are too slow to be used to measure wafers on-line as part of the wafer fabrication process flow, but are suitable for off-line use for purposes such as model training. By way of non-limiting example, a reference metrology system may include a stand-alone optical metrology system, such as a spectroscopic ellipsometer (SE), SE with multiple angles of illumination, SE measuring Mueller matrix elements, a single-wavelength ellipsometer, a beam profile ellipsometer, a beam profile reflectometer, a broadband reflective spectrometer, a single-wavelength reflectometer, an angle-resolved reflectometer, an imaging system, a scatterometer, such as a speckle analyzer, an X-ray based metrology system such as a small angle x-ray scatterometer (SAXS) operated in a transmission or grazing incidence mode, an x-ray diffraction (XRD) system, an x-ray fluorescence (XRF) system, an x-ray photoelectron spectroscopy (XPS) system, an x-ray reflectometer (XRR) system, a Raman spectroscopy system, an atomic force microscopy (AFM) system, a transmission electron microscopy system, a scanning electron microscopy system, a soft X-ray reflectometry system, an imaging based metrology system, a hyperspectral imaging based metrology system, a scatterometry overlay metrology system, or other technologies capable of determining device geometry.

Regularization conditioned measurement model training engine 200 also receives an ensemble of values of a regularization control parameter, R_{1:N}, including N different values of regularization control parameter, R. In general, N is any integer value greater than one.

In some embodiments, a regularization control parameter value of zero implements no regularization and a regularization control parameter value of one implements full regularization. In some of these embodiments, an ensemble of values of a regularization control parameter is a uniform random distribution of values between zero and one. In some other embodiments, an ensemble of values of a regularization control parameter is a Gaussian random distribution of values between zero and one. In general, an ensemble of values of a regularization control parameter includes any combination of values within any suitable range of values of a regularization control parameter. In general, the ensemble of values of a regularization control parameter is synthetically generated, for example, by specific systematic rules, random sampling from any suitable distribution, etc.

Regularization conditioned measurement model training engine 200 trains a machine learning (ML) based measurement model. The ML based measurement model includes one or more one or more regularization blocks controlled by a regularization control parameter. In some examples, the measurement model is a neural network model embedded in neural network module 201. In general, loss evaluation model 202 dynamically controls the weights associated with the neural network model under training.

As depicted in FIG. 2, neural network module 201 evaluates a neural network model, h(.), for data set XDOE 203. The current version of the neural network model generates estimated values of one or more parameters of interest, POI* 209, based on the data set XDOE 203. Estimated values, POI* 209, are communicated to loss evaluation module 202. Loss evaluation module 202 determines the value of an optimization function based on reference data, POI_{DOE} 205, the corresponding values, POI* 209, estimated by the neural network model from X_{DOE} 203, and each of the values of the regularization control parameter, R_{1:N} 206. Loss evaluation module 202 updates the neural network weighting values, W 207, based on the value of the optimization function. The updated neural network weighting values, W 207, are communicated to neural network module 201. Neural network module 201 updates the neural network model with the updated neural network weighting values for the next iteration of the training process.

At each iteration of the training process, the ensemble of values of the regularization control parameter, R_{1:N} 206, are evaluated. Thus, the regularization conditioned measurement model is trained over the ensemble of regularization control parameter values. By adjusting the regularization of the optimization function during the training process, the neural network is trained for a range of regularization control values with less computational effort.

At each iteration, the optimization function drives changes to the weighting values, W, and bias values, b, of the neural network model, h_{w,b}(.) that minimize the optimization function. When the optimization function reaches a sufficiently low value, the measurement model is considered trained, and the trained regularization conditioned measurement model 208 is stored in memory (e.g., memory 132).

In another aspect, computing system 130 is configured as a regularization control parameter optimization engine 210 to optimize the value of a regularization control parameter to ensure optimal measurement performance based on one or more data sets associated with measurements of structures of interest as described herein. In general, the measurement data sets may be synthetically generated, generated based on actual measurements, or both.

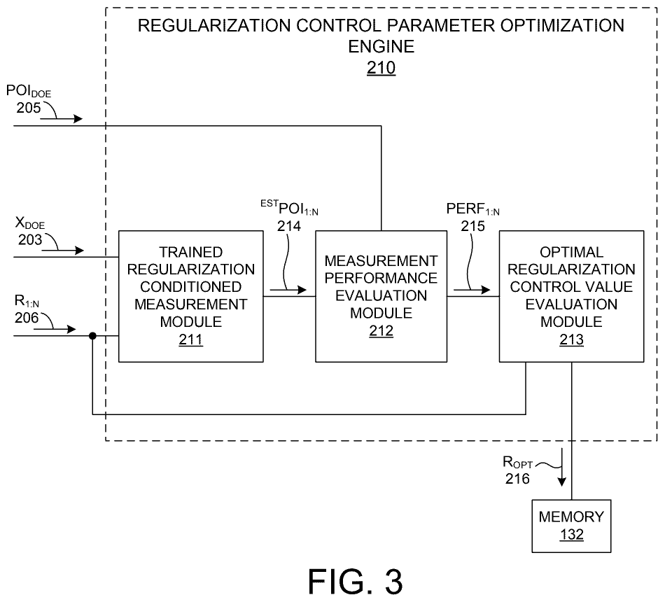

FIG. 3 is a diagram illustrative of an exemplary regularization control parameter optimization engine 210 in one embodiment. As depicted in FIG. 3, regularization control parameter optimization engine 210 receives measurement data, X_{DOE} 203, associated with simulated measurements, actual measurements, or both, of multiple instances of one or more Design of Experiments (DOE) metrology targets disposed on one or more wafers. In addition, regularization control parameter optimization engine 210 receives reference values of one or more parameters of interest, POI_{DOE} 205, associated with the DOE metrology targets and an ensemble of values of a regularization control parameter, R_{1:N} 206, including N different values of regularization control parameter, R.

Regularization control parameter optimization engine 210 includes trained regularization conditioned measurement module 211, measurement performance evaluation module 212, and optimal regularization control value evaluation module 213. Trained regularization conditioned measurement module 211 includes a trained regularization conditioned measurement model, e.g., trained measurement model 208 depicted in FIG. 1. The trained regularization conditioned measurement model estimates values of one or more parameters of interest characterizing one or more structures under measurement, ^{EST}POI_{1:N} 214. The trained regularization conditioned measurement model estimates the values of one or more parameters of interest based at each value of the ensemble of values of the regularization control parameter, R_{1:N}. The estimated values of the parameters of interest, ^{EST}POI_{1:N} 214, are communicated to measurement performance evaluation module 212. Measurement performance evaluation module 212 generates a value of one or more measurement performance metrics, PERF_{1:N} 215, associated with the measurement performed by the trained regularization conditioned measurement model at each value of the regularization control parameter, R_{1:N}. In some embodiments, measurement performance evaluation module 212 generates a value of a measurement performance metric based on estimated values of a parameter of interest and corresponding reference values of the parameter of interest. However, in some other embodiments, measurement performance evaluation module 212 generates a value of a measurement performance metric based on estimated values of a parameter of interest without corresponding reference values of the parameter of interest.

In some embodiments, a measurement performance metric characterizes actual measurement data collected from each of many instances of a structure under measurement. In some embodiments a measurement performance metric is based on data collected from a reference metrology system, nominal DOE parameter values, historical data, domain knowledge about the processes involved in producing the structure, physics, statistical data collected from multiple processes and multiple metrology techniques, or best guess by a user. In some examples, a measurement performance metric is a single point estimate. In other examples, a measurement performance metric is a distribution of estimated values.

In general, a measurement performance metric associated with measurement data collected from one or more structures under measurement provides information about the values of the physical attributes of the structures. By way of non-limiting example, the physical attributes of the structures includes any of measurement precision, measurement accuracy, tool to tool matching, wafer mean, within wafer range, within wafer variations, wafer signature, tracking to reference, wafer to wafer variations, tracking to wafer split, etc.

In some examples, a measurement performance metric includes specific values of a parameter of a structure under measurement and corresponding uncertainties at specific locations on the wafer. In one example, the measurement performance metric is a critical dimension (CD) at a particular location on a wafer and its uncertainty, e.g., the CD is 35 nanometers+/−0.5 nanometers.

In some examples, a measurement performance metric includes a probability distribution of values of a parameter of a structure within a wafer, within a lot of wafers, or across multiple wafer lots. In one example, the CD has a normal distribution with a mean value and a standard deviation, e.g., mean value of CD is 55 nanometers and the standard deviation is 2 nanometers.

In some examples, a measurement performance metric includes a spatial distribution of values of a parameter of interest across a wafer, e.g., a wafer map, and the corresponding uncertainties at each location.

In some examples, a measurement performance metric includes distributions of measured values of parameters of interest across multiple tools to characterize tool to tool matching. The distributions may represent mean values across each wafer, values at each site, or both.

In some examples, a measurement performance metric includes a distribution of measurement precision errors.

In some examples, a measurement performance metric includes a wafer map matching estimates across wafer lots.

In some examples, a measurement performance metric includes one or metrics characterizing the tracking of estimated values of a parameter of interest with reference values of the parameter of interest. In some examples, a measurement performance metric includes one or more metrics characterizing the tracking of estimated values of a parameter of interest to wafer mean for a DOE split experiment. In some examples, the metrics characterizing tracking performance include any of an R2 value, a slope value, and an offset value.

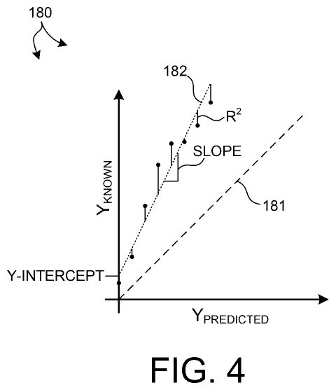

FIG. 4 illustrates a plot 180 indicative of metrics characterizing tracking performance. As illustrated in FIG. 4, the x-location of each data point on plot 180 indicates the predicted value of a parameter of interest and the y-location of each data point indicates the known value (e.g., DOE reference value) of the parameter of interest. Ideal tracking performance is indicated by dashed line 181. If all predicted values perfectly matched the corresponding known, trusted values, all data points would lie on line 181. However, in practice, tracking performance is not perfect. Line 182 illustrates a best fit line to the data points. As depicted in FIG. 4, line 182 is characterized by slope and a y-intercept values, and the correlation between the known and predicted values is characterized by the R² value.

As depicted in FIG. 3, the values of one or more measurement performance metrics, PERF_{1:N} 215, are communicated to optimal regularization control value evaluation module 213. Optimal regularization control value evaluation module 213 generates an optimal value of the regularization control parameter, R_{OPT} 216, based on the values of one or more measurement performance metrics, PERF_{1:N} 215. In some embodiments, the value of the regularization control parameter associated with the best measurement performance is selected as the optimal regularization control value, e.g., lowest value of the root mean squared error of the measured parameter, slope closest to one, highest precision, best tool matching, etc.

In one example, regularization control parameter optimization engine 210 operates on a measurement data set associated with the measurement of a metal gate critical dimension (MGCD) and determines an optimal regularization control value associated with the measurement data set.

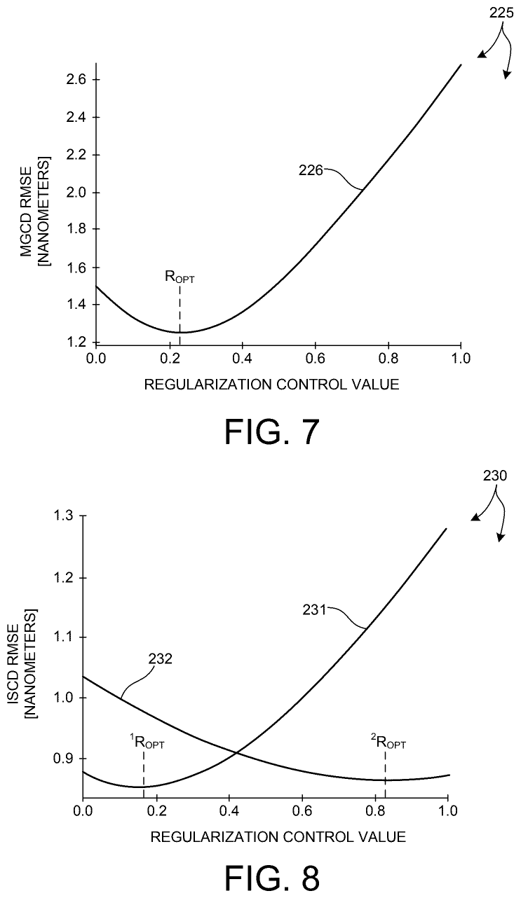

FIG. 7 is a plot 225 of the root mean square error (RMSE) associated with the estimation of the MGCD by a trained measurement model with regularization conditioned by a regularization control value ranging from zero to one. The RMSE value quantifies the error between the value estimated by the trained measurement model and a trusted value of the MGCD. Plotline 226 depicts the root mean square error (RMSE) associated with the estimation of a metal gate critical dimension (MGCD) by a trained measurement model with regularization conditioned by a regularization control value ranging from zero to one. As depicted by plotline 226, the RMSE of the estimated value of the MGCD parameter varies depending on the regularization control value employed during inference. In the example depicted in FIG. 7, the RMSE of the estimated value of the MGCD parameter is minimized at an optimal regularization control value, ROPT, of approximately 0.22. In this example, the best measurement performance, as quantified by the RMSE of the MGCD parameter, is achieved when the regularization control value is 0.22.

In another example, regularization control parameter optimization engine 210 operates on two different measurement data sets associated with the measurement of a inner spacer critical dimension (ISCD) and determines an optimal regularization control value associated with each measurement data set.

FIG. 8 is a plot 230 of the root mean square error (RMSE) associated with the estimation of an inner spacer critical dimension (ISCD) by a trained measurement model with regularization conditioned by a regularization control value ranging from zero to one. Plotlines 231 and 232 depict the root mean square error (RMSE) associated two different measurement data sets. The first set of measurement data is associated with measurements within the distribution of values of the parameter of interest employed to train the regularization conditioned measurement model. In the example depicted in FIG. 8, the RMSE of the estimated value of the ISCD parameter for the first measurement data set is minimized at an optimal regularization control value, ¹R_{OPT}, of approximately 0.18. The second set of measurement data is associated with measurements outside the distribution of values of the parameter of interest employed to train the regularization conditioned measurement model. The RMSE of the estimated value of the ISCD parameter for the second measurement data set is minimized at an optimal regularization control value, ²R_{OPT}, of approximately 0.82.

FIG. 8 illustrates that the measurement performance, as quantified by the RMSE of the ISCD parameter, can be maintained across measurement data sets both within and outside the distribution of values employed during model training by adjusting the regularization control value. This is a significant improvement over existing measurement techniques that do not employ a measurement conditioned measurement model. As illustrated in FIG. 8, if a regularization control value of 0.18 was employed for both measurement data sets, optimal measurement performance would be achieved for the first measurement data set, but not for the second measurement data set. By simply adjusting the regularization control value, a significant reduction in measurement error is achieved without the computational cost of retraining the measurement model.

In another further aspect, a trained regularization conditioned measurement model is employed to estimate values of parameters of interest based on measurements of structures having unknown values of one or more parameters of interest using an optimal regularization control value. The trained regularization conditioned measurement model is employed to estimate values of one or more parameters of interest from actual measurement data (e.g., measured spectra) collected by the measurement system (e.g., metrology system 100).

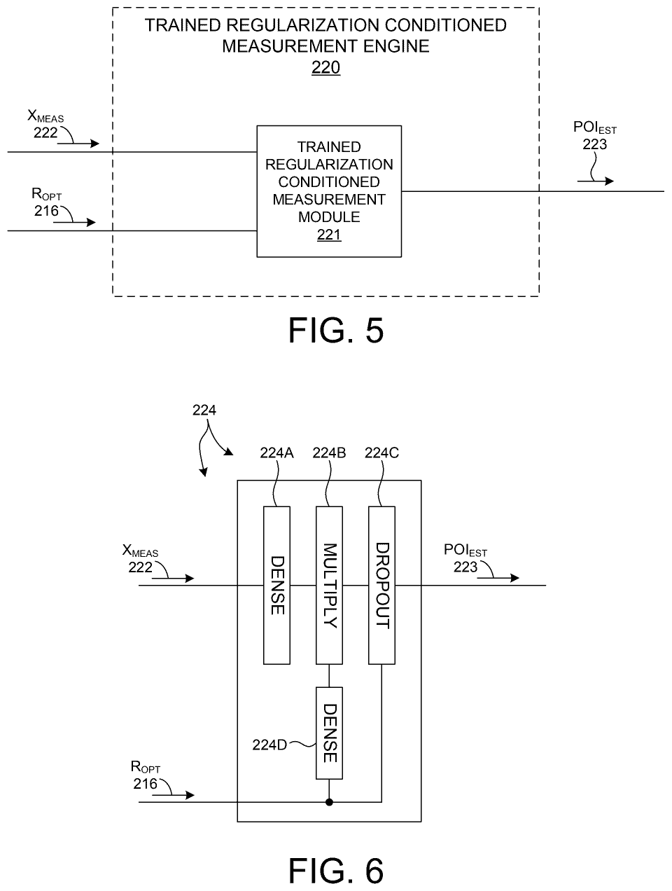

FIG. 5 is a diagram illustrative of an exemplary trained regularization conditioned measurement engine 220 in one embodiment. As depicted in FIG. 5, trained regularization conditioned measurement engine 220 receives measurement data, X_{MEAS} 222, associated with actual measurements of multiple instances of one or more metrology targets disposed on one or more wafers. In addition, trained regularization conditioned measurement engine 220 receives an optimal regularization control value, R_{OPT} 216. Trained regularization conditioned measurement module 221 implements a trained regularization conditioned measurement model that estimates values of one or more parameters of interest, POI_{EST} 223, associated with the measured metrology targets based on measurement data, X_{MEAS} 222. The regularization at inference of the trained regularization conditioned measurement model is controlled by the regularization control value, R_{OPT} 216.

FIG. 6 is a diagram illustrative of a regularization block of a trained regularization conditioned measurement model in one embodiment. In the embodiment depicted in FIG. 6, the trained regularization conditioned measurement model is a multi-layer neural network model including regularization block 224. Regularization block 224 includes a non-linear dense layer 224A interfacing the measurement data, X_{MEAS} 222 with the multiply layer. In addition, regularization block 224 includes a dense layer 224D that expands the scalar valued regularization control value 216 into a vector communicated to the multiply layer. The multiply layer multiplies the output of the non-linear dense layer 224A with the regularization input generated by dense layer 224D. In this manner, the regularization control value controls the regularization of the multiply function, e.g., weights and bias values. In addition, regularization block 224 includes a conditional dropout layer that operates on the output nodes of the multiply layer. As depicted in FIG. 6, the regularization control value is communicated directly to the dropout layer and controls the dropout function. In this manner, both the multiply and dropout layers are subject to regularization and the regularization is controlled by the regularization control value, R_{OPT} 216.

As illustrated in FIG. 8, the optimal regularization control value depends on the distribution of the measurement data employed in the optimization process described with reference to FIG. 3. In some embodiments, once an optimal regularization value is determined, the optimal value is employed in all future measurements using the trained regularization conditioned measurement model.

However, in many realistic measurement scenarios, the distribution of measurement data collected by a metrology system, e.g., metrology system 100, drifts over time, changes abruptly, or both. Process drift, measurement system drift, maintenance events, etc., are some example sources of change in the distribution of measurement data, which, in turn, impacts measurement performance.

In some embodiments, regularization control parameter optimization engine 210 periodically operates on recent measurement data sets that capture changes in the distribution of measurement data to determine an updated, optimal regularization control value. The updated, optimal regularization control value is saved and used for future measurements until another change in measurement performance is detected.

In some embodiments, measurement performance evaluation module 212 is employed to estimate measurement performance associated with current measurements performed using an optimal regularization control value. If measurement performance declines, e.g., falls below a predetermined threshold value, an update of the regularization control value is triggered.

In some embodiments, a measurement uncertainty analysis is performed to estimate measurement performance associated with current measurements performed using an optimal regularization control value. If measurement uncertainty rises, e.g., increases beyond a predetermined threshold value, an update of the regularization control value is triggered.

In some other embodiments, regularization control parameter optimization is performed automatically as an element of the measurement process. Real-time feedback of measurement performance is employed to continually update the regularization control parameter as part of the measurement process. In this manner, changes in measurement data distribution are tracked and the regularization control value continuously updated to provide optimal measurement performance for all measurements. This improves measurement accuracy and robustness in dynamic process environments, in particular.

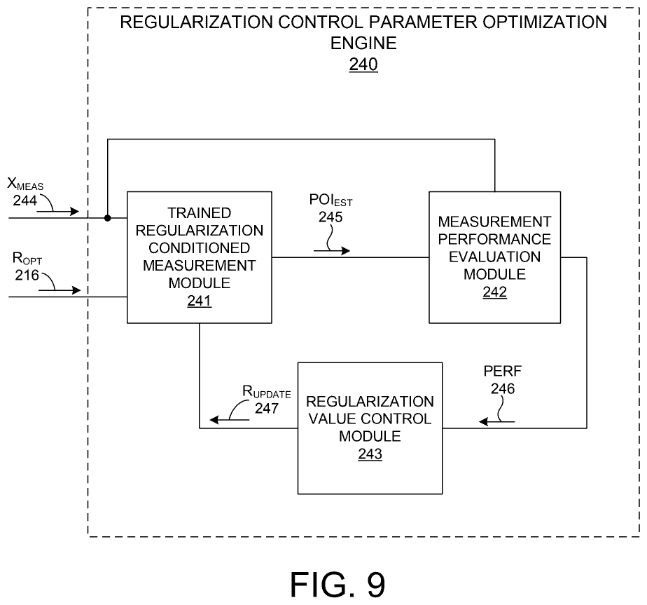

FIG. 9 is a diagram illustrative of a regularization control parameter optimization engine 240 in another embodiment. In the embodiment depicted in FIG. 9, trained regularization conditioned optimization engine 240 includes a trained regularization conditioned measurement module 241, a measurement performance evaluation module 242, and a regularization value control module 243. Trained regularization conditioned measurement module 241 receives an optimal regularization control value 216, and measurement data, X_{MEAS} 244, associated with actual measurements of multiple instances of one or more metrology targets disposed on one or more wafers. Trained regularization conditioned measurement module 241 implements a trained regularization conditioned measurement model that estimates values of one or more parameters of interest, POI_{EST} 245, associated with the measured metrology targets based on measurement data, X_{MEAS} 244. In this measurement instance, the regularization at inference of the trained regularization conditioned measurement model is controlled by the regularization control value, R_{OPT} 216.

The estimated values of the one or more parameters of interest, POI_{EST} 245 and measurement data, X_{MEAS} 244 are communicated to measurement performance evaluation module 242. Measurement performance evaluation module 242 generates a value of one or more measurement performance metrics, PERF 246, associated with the measurement performed by the trained regularization conditioned measurement model at the optimal regularization control value. The measurement performance metric 246 is estimated based on the estimated value of the parameter of interest 245 and the measurement data 244. Regularization value control module 243 receives measurement performance metric 246 and generates an updated value of the regularization control value 247 based on the value of the measurement performance metric 246. In some examples, regularization control module 243 implements a control algorithm that automatically adjusts the regularization control value based on the measurement performance of the model on the measurement data. At the next measurement instance, the regularization of the trained regularization conditioned measurement model is controlled by the updated regulation control value 247, rather than value 216. In this manner, the regularization control parameter optimization engine 240 continuously monitors measurement performance and dynamically updates the regularization control value to optimize measurement performance.

Control module 243 employs a controller that optimizes for one or more measurement objectives. By way of non-limiting example, the controller is any of a Linear Quadratic Regulator (LQR) based controller, a proportional-integral-derivative (PID) controller, an optimal controller, an adaptive controller, a model predictive controller, etc.

In some embodiments, parameters of the controller are optimized for robust performance by a search algorithm, such as a genetic algorithm, a simulated annealing algorithm, a gradient descent algorithm, etc.

In some embodiments, the trained regularization conditioned measurement model is a neural network model including at least one regularization block. Exemplary architectures include, but are not limited to, an ensemble architecture, a convolutional neural network architecture, etc. An ensemble architecture for a trained regularization conditioned neural network based measurement model may include multiple regularization blocks combined to improve the robustness of the measurement model. In some examples, each regularization block may include different hyperparameters to cover a wider range of regularization values.

In general, any combination of regularization blocks and dense layers may be contemplated within the scope of this patent document. In some examples, a regularization block is part of a residual block of a neural network model.

The embodiment described with reference to FIG. 6 illustrates a single regularization block. However, in general, a neural network model may include any number of regularization blocks. In these embodiments, the regularization control value is expanded to a regularization vector using a dense layer. Moreover, different dense layers may be employed to generate different regularization vectors employed by different regularization blocks.

In the embodiment described with reference to FIG. 6, a conditional dropout layer is employed to regularize the output nodes of the regularization block. However, in general, any suitable regularization scheme may be employed to regularize the output nodes of a regularization block, e.g., L1 regularization, L2 regularization, etc. In some embodiments, a combination of different regularization layers may be employed, e.g., hybrid regularization.

In some embodiments, a regularization conditioned measurement model trained as described herein is implemented as a neural network model. In other examples, a measurement model may be implemented as a linear model, a non-linear model, a polynomial model, a response surface model, a support vector machines model, a decision tree model, a random forest model, a kernel regression model, a deep network model, a convolutional network model, or other types of models.

In some examples, a measurement model trained as described herein may be implemented as a combination of models.

In some embodiments, the measurement system employed to collect measurement data from samples having unknown values of one or more parameters of interest is the same measurement system employed to collect the DOE measurement data. In other embodiments, the measurement system is the system simulated to generate the DOE measurement data synthetically. In one example, the actual measurement data includes measured spectra 111 collected by metrology system 100 from one or more metrology targets having unknown values of the one or more parameters of interest.

In general, the trained regularization conditioned measurement model may be employed to estimate values of parameters of interest based on a single measured spectrum or estimate values of parameters of interest simultaneously based on multiple spectra.

In some embodiments, the actual measurement data collected from multiple instances of one or more structures is collected by a particular metrology system. In these embodiments, the regularization conditioned measurement model is trained for a measurement application involving measurements performed by the same metrology system.

In some other embodiments, the actual measurement data collected from multiple instances of one or more structures is collected by multiple instances of a metrology system, i.e., multiple metrology systems that are substantially identical. In these embodiments, the regularization conditioned measurement model is trained for a measurement application involving measurements performed by any of the multiple instances of the metrology system.

In some examples, the measurement data associated with the measurement of each of the multiple instances of one or more Design of Experiments (DOE) metrology targets by a metrology system is simulated. The simulated data is generated from a parameterized model of the measurement of each of the one or more DOE metrology structures by the metrology system.

In some other examples, the measurement data associated with multiple instances of one or more Design of Experiments (DOE) metrology targets is actual measurement data collected by a metrology system or multiple instances of a metrology system. In some of these embodiments, the same metrology system or multiple instances of the metrology system is employed to collect the actual measurement data from the structures.

In a further aspect, trained measurement model performance is validated with test data using error budget analysis. Real measurement data, simulated measurement data, or both, may be employed as test data for validation purposes. For example, measurement performance evaluation modules 212 and 242 described herein may employ error budget analysis to quantify measurement performance expressed as values of one or more measurement performance metrics.

Error budget analysis over real data allows the estimation of the individual contribution of accuracy, tracking, precision, tool matching errors, wafer to wafer consistency, wafer signature consistency, etc. to total error. In some embodiments, test data is designed such that total model error is split into each contributing component.

By way of non-limiting example, real data includes any of the following subsets: real data with reference values for accuracy and tracking calculations. Reference values include slope, offset, R², 3STEYX, mean squared error, 3 sigma error, etc.; real data from measurements of the same site measured multiple times to estimate measurement precision; real data from measurements of the same site measured by different tools to estimate tool-to-tool matching; real data from measurement of sites on multiple wafers to estimate wafer to wafer changes of wafer mean and wafer variance; and real data measurements of multiple wafers to identify wafer signatures, e.g., typical wafer patterns like a bullseye pattern that is expected to be present for given wafers.

In some other examples, a parametrized model of the structure is employed to generate simulated data for error budget analysis. Simulated data is generated such that each parameter of the structure is sampled within its DOE while other parameters are fixed at nominal values. In some examples, other parameters of the simulation, e.g., system model parameters, are included in an error budget analysis. The true reference values of a parameter are known with simulated data, so errors due to changes of each parameter of the structure can be separated.

In some examples, additional simulated data is generated with different noise sampling to calculate precision error.

In some examples, additional simulated data is generated outside of the DOE of the parametrized structure to estimate extrapolation errors.

In yet another further aspect, the measurement results described herein can be used to provide active feedback to a process tool (e.g., lithography tool, etch tool, deposition tool, etc.). For example, values of measured parameters determined based on measurement methods described herein can be communicated to an etch tool to adjust the etch time to achieve a desired etch depth. In a similar way etch parameters (e.g., etch time, diffusivity, etc.) or deposition parameters (e.g., time, concentration, etc.) may be included in a measurement model to provide active feedback to etch tools or deposition tools, respectively. In some example, corrections to process parameters determined based on measured device parameter values and a trained measurement model may be communicated to the process tool. In one embodiment, computing system 130 determines values of one or more parameters of interest during process based on measured signals 111 received from a measurement system. In addition, computing system 130 communicates control commands to a process controller (not shown) based on the determined values of the one or more parameters of interest. The control commands cause the process controller to change the state of a process (e.g., stop the etch process, change the diffusivity, change lithography focus, change lithography dosage, etc.).

In some embodiments, the methods and systems for metrology of semiconductor devices as described herein are applied to the measurement of memory structures. These embodiments enable optical critical dimension (CD), film, and composition metrology for periodic and planar structures.

In some examples, the measurement models are implemented as an element of a SpectraShape® optical critical-dimension metrology system available from KLA-Tencor Corporation, Milpitas, California, USA. In this manner, the model is created and ready for use immediately after the spectra are collected by the system.

In some other examples, the measurement models are implemented off-line, for example, by a computing system implementing AcuShape® software available from KLA-Tencor Corporation, Milpitas, California, USA. The resulting, trained model may be incorporated as an element of an AcuShape® library that is accessible by a metrology system performing measurements.

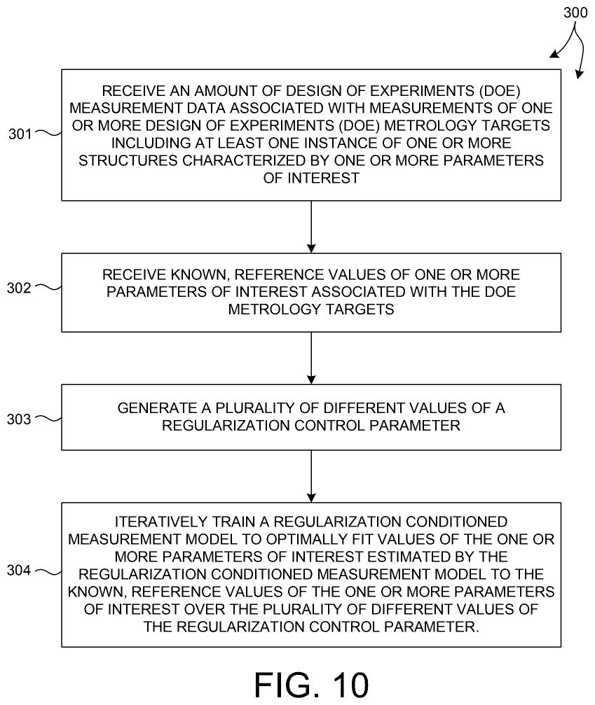

FIG. 10 illustrates a method 300 of training a regularization conditioned measurement model in at least one novel aspect. Method 300 is suitable for implementation by a metrology system such as metrology system 100 illustrated in FIG. 1 of the present invention. In one aspect, it is recognized that data processing blocks of method 300 may be carried out via a pre-programmed algorithm executed by one or more processors of computing system 130, or any other general purpose computing system. It is recognized herein that the particular structural aspects of metrology system 100 do not represent limitations and should be interpreted as illustrative only.

In block 301, an amount of Design of Experiments (DOE) measurement data is received. The DOE measurement data is associated with measurements of one or more Design of Experiments (DOE) metrology targets including at least one instance of one or more structures characterized by one or more parameters of interest.

In block 302, known, reference values of one or more parameters of interest associated with the DOE metrology targets are received.

In block 303, a plurality of different values of a regularization control parameter is generated.

In block 304, a regularization conditioned measurement model is iteratively trained to optimally fit values of the one or more parameters of interest estimated by the regularization conditioned measurement model to the known, reference values of the one or more parameters of interest over the plurality of different values of the regularization control parameter.

In a further embodiment, system 100 includes one or more computing systems 130 employed to perform measurements of semiconductor structures based on measurement data collected in accordance with the methods described herein. The one or more computing systems 130 may be communicatively coupled to one or more spectrometers, active optical elements, process controllers, etc. In one aspect, the one or more computing systems 130 are configured to receive measurement data associated with spectral measurements of structures of wafer 101.

It should be recognized that one or more steps described throughout the present disclosure may be carried out by a single computer system 130 or, alternatively, a multiple computer system 130. Moreover, different subsystems of system 100 may include a computer system suitable for carrying out at least a portion of the steps described herein. Therefore, the aforementioned description should not be interpreted as a limitation on the present invention but merely an illustration.

In addition, the computer system 130 may be communicatively coupled to the spectrometers in any manner known in the art. For example, the one or more computing systems 130 may be coupled to computing systems associated with the spectrometers. In another example, the spectrometers may be controlled directly by a single computer system coupled to computer system 130.

The computer system 130 of system 100 may be configured to receive and/or acquire data or information from the subsystems of the system (e.g., spectrometers and the like) by a transmission medium that may include wireline and/or wireless portions. In this manner, the transmission medium may serve as a data link between the computer system 130 and other subsystems of system 100.

Computer system 130 of system 100 may be configured to receive and/or acquire data or information (e.g., measurement results, modeling inputs, modeling results, reference measurement results, etc.) from other systems by a transmission medium that may include wireline and/or wireless portions. In this manner, the transmission medium may serve as a data link between the computer system 130 and other systems (e.g., memory on-board system 100, external memory, or other external systems). For example, the computing system 130 may be configured to receive measurement data from a storage medium (i.e., memory 132 or an external memory) via a data link. For instance, spectral results obtained using the spectrometers described herein may be stored in a permanent or semi-permanent memory device (e.g., memory 132 or an external memory). In this regard, the spectral results may be imported from on-board memory or from an external memory system. Moreover, the computer system 130 may send data to other systems via a transmission medium. For instance, a measurement model or an estimated parameter value determined by computer system 130 may be communicated and stored in an external memory. In this regard, measurement results may be exported to another system.

Computing system 130 may include, but is not limited to, a personal computer system, mainframe computer system, workstation, image computer, parallel processor, or any other device known in the art. In general, the term “computing system” may be broadly defined to encompass any device having one or more processors, which execute instructions from a memory medium.

Program instructions 134 implementing methods such as those described herein may be transmitted over a transmission medium such as a wire, cable, or wireless transmission link. For example, as illustrated in FIG. 1, program instructions 134 stored in memory 132 are transmitted to processor 131 over bus 133. Program instructions 134 are stored in a computer readable medium (e.g., memory 132). Exemplary computer-readable media include read-only memory, a random access memory, a magnetic or optical disk, or a magnetic tape.

As described herein, the term “critical dimension” includes any critical dimension of a structure (e.g., bottom critical dimension, middle critical dimension, top critical dimension, sidewall angle, grating height, etc.), a critical dimension between any two or more structures (e.g., distance between two structures), and a displacement between two or more structures (e.g., overlay displacement between overlaying grating structures, etc.). Structures may include three dimensional structures, patterned structures, overlay structures, etc.

As described herein, the term “critical dimension application” or “critical dimension measurement application” includes any critical dimension measurement.

As described herein, the term “metrology system” includes any system employed at least in part to characterize a specimen in any aspect, including measurement applications such as critical dimension metrology, overlay metrology, focus/dosage metrology, and composition metrology. However, such terms of art do not limit the scope of the term “metrology system” as described herein. In addition, the system 100 may be configured for measurement of patterned wafers and/or unpatterned wafers. The metrology system may be configured as a LED inspection tool, edge inspection tool, backside inspection tool, macro-inspection tool, or multi-mode inspection tool (involving data from one or more platforms simultaneously), and any other metrology or inspection tool that benefits from the techniques described herein.

Various embodiments are described herein for a semiconductor measurement system that may be used for measuring a specimen within any semiconductor processing tool (e.g., an inspection system or a lithography system). The term “specimen” is used herein to refer to a wafer, a reticle, or any other sample that may be processed (e.g., printed or inspected for defects) by means known in the art.

As used herein, the term “wafer” generally refers to substrates formed of a semiconductor or non-semiconductor material. Examples include, but are not limited to, monocrystalline silicon, gallium arsenide, and indium phosphide. Such substrates may be commonly found and/or processed in semiconductor fabrication facilities. In some cases, a wafer may include only the substrate (i.e., bare wafer). Alternatively, a wafer may include one or more layers of different materials formed upon a substrate. One or more layers formed on a wafer may be “patterned” or “unpatterned.” For example, a wafer may include a plurality of dies having repeatable pattern features.

A “reticle” may be a reticle at any stage of a reticle fabrication process, or a completed reticle that may or may not be released for use in a semiconductor fabrication facility. A reticle, or a “mask,” is generally defined as a substantially transparent substrate having substantially opaque regions formed thereon and configured in a pattern. The substrate may include, for example, a glass material such as amorphous SiO2. A reticle may be disposed above a resist-covered wafer during an exposure step of a lithography process such that the pattern on the reticle may be transferred to the resist.

One or more layers formed on a wafer may be patterned or unpatterned. For example, a wafer may include a plurality of dies, each having repeatable pattern features. Formation and processing of such layers of material may ultimately result in completed devices. Many different types of devices may be formed on a wafer, and the term wafer as used herein is intended to encompass a wafer on which any type of device known in the art is being fabricated.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

Although certain specific embodiments are described above for instructional purposes, the teachings of this patent document have general applicability and are not limited to the specific embodiments described above. Accordingly, various modifications, adaptations, and combinations of various features of the described embodiments can be practiced without departing from the scope of the invention as set forth in the claims.

What is claimed is:

1. A system comprising:
a metrology tool including an illumination source and a detector configured to collect a first amount of measurement data from measurements of one or more structures disposed on a first wafer, the one or more structures characterized by one or more parameters of interest; and
a computing system configured to:
receive an amount of Design of Experiments (DOE) measurement data associated with measurements of one or more Design of Experiments (DOE) metrology targets including at least one instance of the one or more structures characterized by the one or more parameters of interest;
receive known, reference values of one or more parameters of interest associated with the DOE metrology targets;
generate a plurality of different values of a regularization control parameter; and
iteratively train a regularization conditioned measurement model to optimally fit values of the one or more parameters of interest estimated by the regularization conditioned measurement model to the known, reference values of the one or more parameters of interest over the plurality of different values of the regularization control parameter.

2. The system of claim 1, the computing system further configured to:
receive the first amount of measurement data from the measurements of the one or more structures disposed on the first wafer;
estimate values of the parameters of interest characterizing the one or more structures from the amount of measurement data based on the trained regularization conditioned measurement model evaluated at each value of the plurality of values of the regularization control parameter; and
select an optimal value of the regularization control parameter based on a measurement performance of the trained regularization conditioned measurement model at each value of the plurality of values of the regularization control parameter.

3. The system of claim 1, wherein the metrology tool collects a second amount of measurement data from measurements of the one or more structures disposed on a second wafer, the one or more structures characterized by one or more parameters of interest having unknown values, the computing system further configured to:
estimate values of the parameters of interest characterizing the one or more structures disposed on the second wafer from the second amount of measurement data based on the trained regularization conditioned measurement model evaluated at an optimal value of the regularization control parameter.

4. The system of claim 1, the computing system further configured to:
receive the first amount of measurement data from the measurements of the one or more structures disposed on the first wafer;
estimate values of the one or more parameters of interest characterizing the one or more structures from the first amount of measurement data based on the trained regularization conditioned measurement model evaluated at an optimal value of the regularization control parameter; and
adjust the optimal value of the regularization control parameter based on a measurement performance of the trained regularization conditioned measurement model evaluated at the optimal value of the regularization control parameter.

5. The system of claim 4, wherein the adjusting of the optimal value of the regularization control parameter is controlled by any of a Linear Quadratic Regulator (LQR) based controller, a proportional-integral-derivative (PID) controller, an optimal controller, an adaptive controller, and a model predictive controller.

6. The system of claim 1, wherein at least a portion of the amount of Design of Experiments (DOE) measurement data associated with measurements of one or more Design of Experiments (DOE) metrology targets is generated by a simulation.

7. The system of claim 6, wherein the reference values of one or more parameters of interest associated with the DOE metrology targets are known values associated with the simulation.

8. The system of claim 1, wherein the reference values of one or more parameters of interest associated with the DOE metrology targets are measured by a trusted, reference metrology system.

9. The system of claim 1, wherein at least a portion of the amount of Design of Experiments (DOE) measurement data is collected from actual measurements of one or more Design of Experiments (DOE) metrology targets disposed on a second wafer.

10. The system of claim 1, wherein the trained regularization conditioned measurement model is any of a neural network model, a linear model, a non-linear model, a polynomial model, a response surface model, a support vector machines model, a decision tree model, a random forest model, a kernal regression model, a deep network model, and a convolutional network model.

11. The system of claim 1, wherein the metrology tool is an optical based metrology tool, an x-ray based metrology tool, or a combination thereof.

12. A method comprising:
receiving an amount of Design of Experiments (DOE) measurement data associated with measurements of one or more Design of Experiments (DOE) metrology targets including at least one instance of one or more structures characterized by one or more parameters of interest;
receiving known, reference values of one or more parameters of interest associated with the DOE metrology targets;
generating a plurality of different values of a regularization control parameter; and
iteratively training a regularization conditioned measurement model to optimally fit values of the one or more parameters of interest estimated by the regularization conditioned measurement model to the known, reference values of the one or more parameters of interest over the plurality of different values of the regularization control parameter.

13. The method of claim 12, further comprising:
receiving the first amount of measurement data from the measurements of the one or more structures disposed on the first wafer;
estimating values of the parameters of interest characterizing the one or more structures from the amount of measurement data based on the trained regularization conditioned measurement model evaluated at each value of the plurality of values of the regularization control parameter; and
selecting an optimal value of the regularization control parameter based on a measurement performance of the trained regularization conditioned measurement model at each value of the plurality of values of the regularization control parameter.

14. The method of claim 12, further comprising:
estimating values of the parameters of interest characterizing the one or more structures disposed on the second wafer from a second amount of measurement data based on the trained regularization conditioned measurement model evaluated at an optimal value of the regularization control parameter, wherein the second amount of measurement data is collected from measurements of the one or more structures disposed on a second wafer, the one or more structures characterized by one or more parameters of interest having unknown values.

15. The method of claim 12, further comprising:
receiving the first amount of measurement data from the measurements of the one or more structures disposed on the first wafer;
estimating values of the one or more parameters of interest characterizing the one or more structures from the first amount of measurement data based on the trained regularization conditioned measurement model evaluated at an optimal value of the regularization control parameter; and
adjusting the optimal value of the regularization control parameter based on a measurement performance of the trained regularization conditioned measurement model evaluated at the optimal value of the regularization control parameter.

16. The method of claim 15, wherein the adjusting of the optimal value of the regularization control parameter is controlled by any of a Linear Quadratic Regulator (LQR) based controller, a proportional-integral-derivative (PID) controller, an optimal controller, an adaptive controller, and a model predictive controller.

17. The method of claim 12, wherein at least a portion of the amount of Design of Experiments (DOE) measurement data associated with measurements of one or more Design of Experiments (DOE) metrology targets is generated by a simulation, and wherein the reference values of one or more parameters of interest associated with the DOE metrology targets are known values associated with the simulation.

18. A system comprising:
a metrology tool including an illumination source and a detector configured to collect a first amount of measurement data from measurements of one or more structures disposed on a first wafer, the one or more structures characterized by one or more parameters of interest; and
a non-transitory, computer-readable medium storing instructions that, when executed by one or more processors, causes the one or more processors to:
receive an amount of Design of Experiments (DOE) measurement data associated with measurements of one or more Design of Experiments (DOE) metrology targets including at least one instance of the one or more structures characterized by the one or more parameters of interest;
receive known, reference values of one or more parameters of interest associated with the DOE metrology targets;
generate a plurality of different values of a regularization control parameter; and
iteratively train a regularization conditioned measurement model to optimally fit values of the one or more parameters of interest estimated by the regularization conditioned measurement model to the known, reference values of the one or more parameters of interest over the plurality of different values of the regularization control parameter.

19. The system of claim 18, the non-transitory, computer-readable medium further storing instructions that, when executed by one or more processors, causes the one or more processors to:
receive the first amount of measurement data from the measurements of the one or more structures disposed on the first wafer;
estimate values of the parameters of interest characterizing the one or more structures from the amount of measurement data based on the trained regularization conditioned measurement model evaluated at each value of the plurality of values of the regularization control parameter; and
select an optimal value of the regularization control parameter based on a measurement performance of the trained regularization conditioned measurement model at each value of the plurality of values of the regularization control parameter.

20. The system of claim 1, the non-transitory, computer-readable medium further storing instructions that, when executed by one or more processors, causes the one or more processors to:
estimate values of the parameters of interest characterizing one or more structures disposed on a second wafer from a second amount of measurement data collected from the second wafer based on the trained regularization conditioned measurement model evaluated at an optimal value of the regularization control parameter.
